(19) United States
(12) Patent Application Publication
(10) Pub. No.: US 2008/0048740 A1
(43) Pub. Date: Feb. 28, 2008

(54) METHOD AND APPARATUS FOR GENERATING CLOCK SIGNAL

(76) Inventor: Yu-Pin Chou, Miao- Li Hsien (TW)

Correspondence Address: NORTH AMERICA INTELLECTUAL PROPERTY CORPORATION, P.O. BOX 506, MERRIFIELD, VA, 22116, US

(21) Appl. No.: 11/773,940

(22) Filed: Jul. 5, 2007

(30) Foreign Application Priority Data
Jul. 13, 2006 (TW) 095125632

(51) Int. Cl. H03L 7/06

(52) U.S. Cl. 327/156

(57) ABSTRACT

The present invention relates to an apparatus and a method thereof for generating a clock signal. The apparatus includes a clock generating module and at least one delay stage. The clock generating module receives a reference signal through a first signal path, receives a feedback signal through a second signal path, and provides a clock signal to a third signal path according to the reference signal, wherein the feedback signal corresponds to the clock signal. The at least one delay stage is located on at least one of the first, second, and third signal paths for providing a corresponding delay on the signal path at which the at least one delay stage is positioned.

### BACKGROUND OF THE INVENTION

1. Field of the Invention

The present invention relates to an electronic circuit, and more particularly, to methods and apparatuses for generating clock signals.

2. Description of the Prior Art

A clock generator is very important for many electronic appliances and has a significant influence for system performance. In most electronic appliances, the clock generator for generating required clock signals is typically implemented by a phase-locked loop (PLL) or a delay-locked loop (DLL). For example, when a PLL is utilized to generate an output clock signal corresponding to a reference signal as a sampling clock of the reference signal, the sampling clock is aligned with the reference signal or the sampling clock have a predetermined phase relationship with the reference signal to ensure the reliability of the sampling result.

The conventional PLL or DLL utilizes a phase-frequency detector (PFD) to detect the frequency difference/phase difference between the reference signal and the output clock signal, or to detect the frequency difference/phase difference between the reference signal and a frequency-divided signal derived from the output clock signal. Then, the frequency or phase of the output clock signal is adjusted according to the detecting results of the PFD. However, the conventional PLL or DLL does not take the delay effect caused by physical circuit components or wires into consideration in design to have an unpredictable phase error between the output clock signal and the reference signal. Further, the aforementioned delay effect may vary with process variations, temperature, and operating voltages of components on the signal paths.

### SUMMARY OF THE INVENTION

It is therefore an objective of the claimed invention to provide methods and apparatuses for generating clock signals that take the delay effect into consideration and compensate for it to solve the above-mentioned problems.

An embodiment of a clock generating apparatus is disclosed comprising: a clock generating module for receiving a reference signal through a first signal path, receiving a feedback signal through a second signal path, and providing a clock signal to a third signal path according to the reference signal, wherein the feedback signal corresponds to the clock signal; and at least one delay stage located on at least one of the first, second, and third signal paths for providing a corresponding delay to the signal path at which the delay stage is positioned so that the clock signal and the reference signal have a predetermined phase relationship.

An embodiment of a method for generating a clock signal is disclosed comprising: receiving a reference signal through a first signal path; receiving a feedback signal through a second signal path; providing a clock signal to a third signal path according to the reference signal, wherein the feedback signal corresponds to the clock signal; and providing a corresponding delay to at least one of the first, second, and third signal paths so that the clock signal and the reference signal have a predetermined phase relationship.

An embodiment of a clock generating apparatus is disclosed comprising: a clock generating module for receiving a reference signal through a first signal path, receiving a feedback signal through a second signal path, and providing a clock signal according to the reference signal, wherein the feedback signal corresponds to the clock signal and the first and second signal paths have different delays; and at least one delay stage located on at least one of the first, and second signal paths for providing a corresponding delay to the signal path at which the delay stage is positioned to compensate the delay of the signal path.

An embodiment of a clock generating apparatus is disclosed comprising: a clock generating module for receiving a reference signal through a first signal path, receiving a feedback signal through a second signal path, and generating a clock signal on a third signal path according to the reference signal, wherein the feedback signal corresponds to the clock signal; and at least one delay stage located on at least one of the first and second signal paths for providing a corresponding delay on the signal path at which the delay stage is positioned so that the feedback signal and the reference signal have a predetermined phase difference.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified block diagram of a clock generating apparatus according to a first embodiment of the present invention.

FIG. 2 is a simplified block diagram of a clock generating apparatus according to a second embodiment of the present invention.

### DETAILED DESCRIPTION

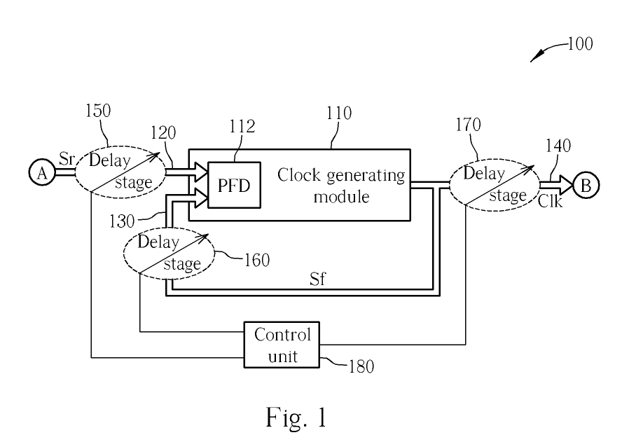

Please refer to FIG. 1, which shows a simplified block diagram of a clock generating apparatus 100 according to a first embodiment of the present invention. In FIG. 1, a node A represents an output terminal of a preceding stage of the clock generating apparatus 100 (e.g., a signal source of a reference signal Sr), and a node B represents an input terminal of a following stage of the clock generating apparatus 100 (e.g., a sampling circuit, an ADC, etc). The clock generating apparatus 100 utilizes a clock generating module 110 to generate a clock signal Clk according to the reference signal Sr. In practice, the clock generating module 110 may be implemented by a phase-locked loop (PLL) or a delay-locked loop (DLL). The clock generating module 110 comprises a phase-frequency detector 112 for receiving the reference signal Sr through a first signal path 120, receiving a feedback signal Sf through a second signal path 130, and detecting the phase relationship between the reference signal Sr and the feedback signal Sf. Other components (not shown) in the clock generating module 110 generate the clock signal Clk according to the detecting result of the phase-frequency detector 112. In one embodiment, the clock generating module 110 outputs the clock signal Clk to a third signal path 140.

In practical applications, components or wires on the first signal path 120, the second signal path 130, or the third signal path 140 cause certain delay effects. As mentioned above, the delay effect of these signal paths results in an unpredictable phase error existing between a signal of the node A (i.e., the reference signal Sr) and a signal of the node B (i.e., the clock signal Clk). To alleviate this problem, at least one of the first signal path 120, the second signal path 130, and the third signal path 140 is provided with a delay stage in this embodiment. As shown in FIG. 1, a first delay stage 150, a second delay stage 160, and a third delay stage 170 may be located on the first signal path 120, the second signal path 130, and the third signal path 140, respectively. Each delay stage is utilized to provide a corresponding delay on the signal path at which the delay stage is positioned so that the signal of the node A (i.e., the reference signal Sr) and the signal of the node B (i.e., the clock signal Clk) have a predetermined phase relationship. In circuitry design, the delay amount utilized to compensate each signal path can be estimated to generate an estimating result by using simulation approaches, and the delay of each delay stage can be programmed according to the estimating result. In practice, each of the first delay stage 150, the second delay stage 160, and the third delay stage 170 can be implemented with buffers, delay cells, multiplexers, flip-flops, MOS transistors, capacitors, filters, or other delaying components.

In addition, each of the first delay stage 150, the second delay stage 160, and the third delay stage 170 can be designed to be a programmable delay stage or a controlled delay cell. In this case, the clock generating module 110 can utilize a control unit 180 to adjust the delays of all or a portion of the delay stages 150, 160, and 170 according to the operating environment of the clock generating module 110. For example, the control unit 180 may correspondingly adjust the delays of all or a portion of the delay stages 150, 160, and 170 according to at least one of the temperature, the operating voltage, and/or other environment factors of the clock generating module 110, so that the signals on the nodes A and B have a predetermined phase relationship with respect to different operating environments.

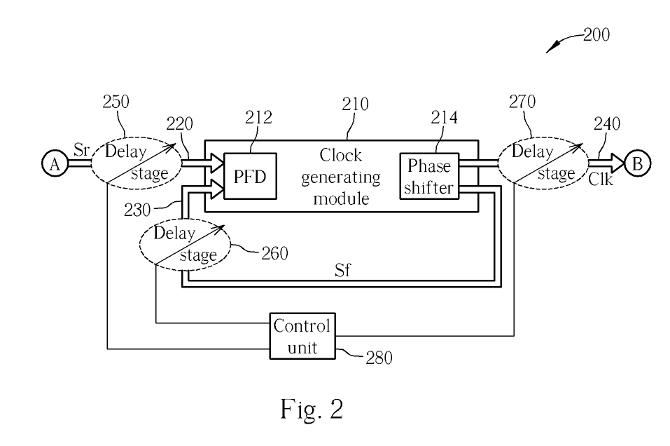

FIG. 2 is a simplified block diagram of a clock generating apparatus 200 according to a second embodiment of the present invention. As shown in FIG. 2, the clock generating apparatus 200 of this embodiment comprises a phase shifter 214. Other components (not shown) in a clock generating module 210 generate an output signal according to the detecting result of a phase-frequency detector 212. The phase shifter 214 then generates a clock signal Clk and a feedback signal Sf according to the output signal, wherein the clock signal Clk and the feedback signal Sf have a predetermined phase difference. The operations and implementations of the phase shifter 214 are well known in the art, and further details are therefore omitted herein for the sake of brevity.

Similarly, in order to alleviate unpredictable phase error between the signals of the nodes A and B (i.e., the reference signal Sr and the clock signal Clk) caused by the delay effect of the first signal path 220, the second signal path 230, or the third signal path 240, at least one of the first signal path 220, the second signal path 230, and the third signal path 240 can be provided with a delay stage. For example, a first delay stage 250, a second delay stage 260, and a third delay stage 270 are respectively located on the first signal path 220, the second signal path 230, and the third signal path 240 in this embodiment. Each delay stage is utilized to provide a corresponding delay on the signal path at which the delay stage is positioned so that the reference signal Sr and the clock signal Clk have a predetermined phase relationship, e.g., the phase of the clock signal Clk is aligned with the phase of the reference signal Sr. Similar to the previous embodiment, the delay of each delay stage may be estimated by using simulation approaches in circuitry design.

In a preferred embodiment, each of the delay stages 250, 260, and 270 is either a programmable delay stage or a controlled delay cell. Additionally, a control unit 280 is utilized in the clock generating apparatus 200 to adjust the delay of each of the delay stages according to at least one of the temperature, the operating voltage, and/or other environment factors, so that the signals on the nodes A and B can maintain a predetermined phase relationship.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A clock generating apparatus comprising:
a clock generating module for receiving a reference signal through a first signal path, receiving a feedback signal through a second signal path, and providing a clock signal to a third signal path according to the reference signal, wherein the feedback signal is corresponsive of the clock signal; and
at least one delay stage arranged on at least one of the first, second, and third signal paths, for providing a corresponding delay on the signal path at which the delay stage is positioned so that the clock signal and the reference signal have a predetermined phase relationship.

2. The apparatus of claim 1, wherein there is a predetermined phase difference between the reference signal and the feedback signal.

3. The apparatus of claim 1, wherein the clock generating module comprises a phase-locked loop (PLL).

4. The apparatus of claim 1, wherein the clock generating module comprises a delay-locked loop (DLL).

5. The apparatus of claim 1, further comprising:
a control unit coupled to the delay stage for adjusting the corresponding delay according to the operating environment of the clock generating module.

6. The apparatus of claim 1, wherein the corresponding delay results in the phase of the clock signal to be aligned with the phase of the reference signal.

7. The apparatus of claim 1, wherein the clock generating module further comprises:
a phase frequency detector, for receiving the reference signal and the feedback signal, detecting a phase difference of the reference signal and the feedback signal, and providing a detecting result, where the detecting result is an information for generating the clock signal.

8. A method for generating a clock signal, comprising:
receiving a reference signal through a first signal path;
receiving a feedback signal through a second signal path;
providing a clock signal to a third signal path according to the reference signal, wherein the feedback signal is corresponsive of the clock signal; and
providing a corresponding delay on at least one of the first, second, and third signal paths so that the clock signal and the reference signal have a predetermined phase relationship.

9. The method of claim 8, wherein there is a predetermined phase difference between the reference signal and the feedback signal.

10. The method of claim 8, further comprising:
adjusting the corresponding delay according to the operating environment of generating the clock signal.

11. The method of claim 8, wherein the corresponding delay results in the phase of the clock signal to be aligned with the phase of the reference signal.

12. A clock generating apparatus comprising:
a clock generating module for receiving a reference signal through a first signal path, receiving a feedback signal through a second signal path, and generating a clock signal according to the reference signal, wherein the first and second signal paths have different delays and the feedback signal is corresponsive of the clock signal; and
at least one delay stage arranged on at least one of the first and second signal paths, for providing a corresponding delay on the signal path at which the delay stage is positioned to compensate a difference between the delays of the first and second signal paths.

13. The apparatus of claim 12, wherein the at least one delay stage comprises at least one of a programmable delay stage and a controlled delay cell.

14. The apparatus of claim 12, further comprising:
a control unit coupled to the delay stage for adjusting the corresponding delay according to the operating environment of the clock generating module.

15. The clock generating apparatus of claim 12, wherein the clock generating module outputs the clock signal through a third signal path, and the apparatus further comprises:
a second delay stage for providing a second delay on the third signal path to delay the clock signal.

16. The clock generating apparatus of claim 15, further comprising:
a control unit coupled to at least one of the delay stage and the second delay stage for adjusting the at least one of delay of the delay stage and the second delay stage according to the operating environment of the clock generating module.
